(19) United States
(12) Patent Application Publication
(10) Pub. No.: US 2024/0178085 A1
(43) Pub. Date: May 30, 2024

(54) OPEN CAVITY INTEGRATED CIRCUIT

(71) Applicant: TEXAS INSTRUMENTS INCORPORATED, Dallas, TX (US)

(72) Inventors: STEVEN ALFRED KUMMERL, Carrollton, TX (US); SREENIVASAN K. KODURI, Dallas, TX (US); SOPHIA DELPAK, Richardson, TX (US); LAURA MAY ANTIONETTE CLEMENTE, MABALACAT CITY (PH)

(21) Appl. No.: 18/070,523

(22) Filed: Nov. 29, 2022

(51) Int. Cl. H01L 23/24; H01L 21/56; H01L 23/00; H01L 23/31

(52) U.S. Cl. CPC H01L 23/24; H01L 21/56; H01L 23/3185; H01L 23/3192; H01L 24/32; H01L 24/48; H01L 24/73; H01L 23/49513

(57) ABSTRACT

An electronic device includes a substrate and a die having an active surface disposed on the substrate. A sensor is in communication with the active surface of the die. A ring encircles the sensor and includes a cylindrical wall and a cap, where the cap has a partial circular shape that extends beyond each side of the wall. A mold compound covers the die and abuts an outer surface of the wall thereby forming a cavity in the mold compound to expose the sensor to an environment external to the electronic device.

### TECHNICAL FIELD

The present disclosure relates to an electronic device and more specifically, to an open cavity integrated circuit package that includes a mushroom capped plated wall in the cavity.

### BACKGROUND

Open cavity packages (OCP) are used as sensor packages to measure various physical properties of an environment such as humidity, temperature, optics, sound, pressure, adverse environmental conditions, etc. Thus, OCP's include a sensor to sense the physical property and other circuitry to process the sensed physical property. As a result, the sensor must be exposed to the environment while the other circuitry must be protected from the environment so as not to damage the circuitry. Accordingly, OCP's are fabricated such that the sensor is exposed to the environment, but the other circuitry is covered and protected by a mold compound. Thus, OCP's include a cavity that extends through the mold compound down to a surface of a die. The sensor is disposed on a surface of the die in the cavity and is therefore exposed directly to the environment to be tested. During the molding process, it is imperative that the mold compound does not enter the cavity.

### SUMMARY

In described examples, an electronic device includes a substrate and a die having an active surface disposed on the substrate. A sensor is in communication with the active surface of the die. A ring encircles the sensor and includes a cylindrical wall and a cap, where the cap has a partial circular shape that extends beyond each side of the wall. A mold compound covers the die and abuts an outer surface of the wall thereby forming a cavity in the mold compound to expose the sensor to an environment external to the electronic device.

In another described example, a method includes providing a die including a sensor and depositing a ring on the die where the die encircling the sensor. The die is placed on a substrate and both the die and the substrate are placed in a mold chase that includes film assist material. The mold chase clamps the die and the substrate such that the film assist material layer contacts cap of the ring. A mold compound is injected into the mold chase and abuts an outer surface of the ring. The ring and the film assist material layer prevent the mold compound from entering an interior of the ring.

In still another described example, an electronic device includes fabricating a die assembly comprising providing a die having an active surface, where the die includes a sensor. A stress relief layer is deposited on the active surface of the die and a seed layer is deposited on the stress relief layer. A photoresist material layer is deposited over the die and is patterned to form a ring shaped opening on the seed layer. Metal is electroplated on the seed layer in the ring shaped opening to form a metal ring. A sensor is placed on the active surface of the die inside the metal ring and the die assembly is placed on a substrate. The die assembly and the substrate are placed in a mold chase where the mold chase includes film assist material. The mold chase clamps the die assembly and the substrate such that the film assist material layer contacts a cap of the metal ring. A mold compound is injected into the mold chase and abuts an outer surface of the metal ring. The metal ring and the film assist material prevent the mold compound from entering an interior of the metal ring

### BRIEF DESCRIPTION OF THE DRAWINGS

FIG. 1 is a cross section view of an example electronic device.

FIG. 2 is a top view of a wafer that includes dies.

FIG. 3 illustrates a cross section view of a singulated die from the wafer in FIG. 2 in the early stages of fabrication of a die assembly.

FIG. 4 illustrates a cross section view of the singulated die in FIG. 3 that includes a sensor integrated into the die.

FIG. 5 illustrates a cross section view of the die assembly in FIG. 4 including an optional die polymer layer.

FIG. 6 illustrates a cross section view of the die assembly of FIG. 5 undergoing a first material deposition process.

FIG. 7 illustrates a cross section view of the die assembly of FIG. 6 undergoing a second material deposition process.

FIG. 8 illustrates a side view of the die assembly of FIG. 7 undergoing a photoresist material layer patterning.

FIG. 9 illustrates a side view of the die assembly of FIG. 8 undergoing an electroplating process.

FIGS. 10A and 10B are close up, cross section views of the electroplating process in FIG. 9.

FIG. 11 illustrates a cross section view of the die assembly of FIG. 9 after undergoing an etch process to strip the photoresist material layer and partially etch a seed layer.

FIG. 12 illustrates a cross section view of a leadframe based substrate in the early stages of assembly of an electronic device.

FIG. 13 illustrates a cross section view of the electronic device of FIG. 12 undergoing deposition of a die attach material.

FIG. 14 illustrates a cross section view of the electronic device with the die assembly of FIG. 11 attached to the leadframe.

FIG. 15 illustrates a cross section view of the electronic device of FIG. 14 undergoing a wire bonding process.

FIG. 16 illustrates a cross section view of the electronic device of FIG. 15 being placed in a mold chase.

FIG. 17 illustrates a cross section view of the electronic device of FIG. 16 in the mold chase undergoing a vacuum.

FIG. 18 illustrates a cross section view of the electronic device of FIG. 17 after undergoing injection of a mold compound a deposition of an interconnect.

FIG. 19 illustrates a cross section view of the electronic device of FIG. 18 after the electronic device is removed from the mold chase.

FIG. 20 illustrates a cross section view of a modification of the electronic device of FIGS. 1 and 19 that does not include the optional die polymer layer.

FIG. 21 illustrates a cross section view of a modification of the electronic device of FIGS. 1 and 19 that does not include an optional polymer or metal layer.

FIG. 22 illustrates a cross section view of a modification of the electronic device of FIGS. 1 and 19 that does not include an optional plated metal layer.

FIG. 23 illustrates a cross section view of a modification of the electronic device of FIGS. 1 and 19 that does not include the optional die polymer layer and the optional polymer or metal layer.

FIG. 24 illustrates a cross section view of a modification of the electronic device of FIGS. 1 and 19 that does not include the optional die polymer layer and the optional plated metal structure.

FIG. 25 illustrates a cross section view of a modification of the electronic device of FIGS. 1 and 19 that does not include the optional polymer or metal layer and the optional plated metal structure.

FIG. 26 illustrates a cross section view of a modification of the electronic device of FIGS. 1 and 19 that does not include the optional die polymer layer, the optional polymer or metal layer, and the optional plated metal structure.

### DETAILED DESCRIPTION

Open cavity package (OCP) integrated circuits are used as sensor packages to measure various physical properties of an environment such as humidity, temperature, optics, sound, pressure, adverse environmental conditions, etc. Thus, OCP's include a sensor disposed in a cavity of the OCP to sense the respective physical property and other circuitry to process the sensed physical property. As a result, the sensor is exposed to the environment while the other circuitry must be protected from the environment so as not to damage the circuitry.

Current fabrication processes include complex and expensive molding equipment that is limited in its ability to create small packages with small sensor cavities in the OCP while simultaneously preventing any mold compound from entering the cavity. In addition, the complex and expensive molding equipment used to create the sensor cavities is package-specific, meaning that the equipment generally cannot be re-used for multiple types of OCP's. Rather, different equipment is required for different types of OCP's. Investment in different types of equipment introduces significant increases in design costs, manufacturing costs, development time, and manufacturing time.

Disclosed herein is an electronic device and more specifically, an open cavity package (OCP) integrated circuit and method of fabricating the OCP that overcomes the challenges described above. The OCP includes a ring (e.g., plated metal ring) having a cylindrical wall and a partially circular or semi-circular cap. Thus, a cross-section view of the ring and cap essentially has a mushroom-shape. The ring is positioned on a die and a sensor is disposed on the die inside the ring. During the molding process, the OCP is placed in a mold chase. A film is disposed between the ring and the mold chase. When the mold chase clamps the OCP, the film contacts the cap portion of the ring and prevents the mold compound from flowing inside the ring and onto the sensor. Thus, a cavity is formed in the mold compound where the sensor resides. The ring may be composed of metal or non-metal materials, and they may be grown on the semiconductor die using a plating process or printing process using ink containing metal or non-metal materials or may be manufactured separately from the semiconductor die and coupled to the semiconductor die using an adhesive.

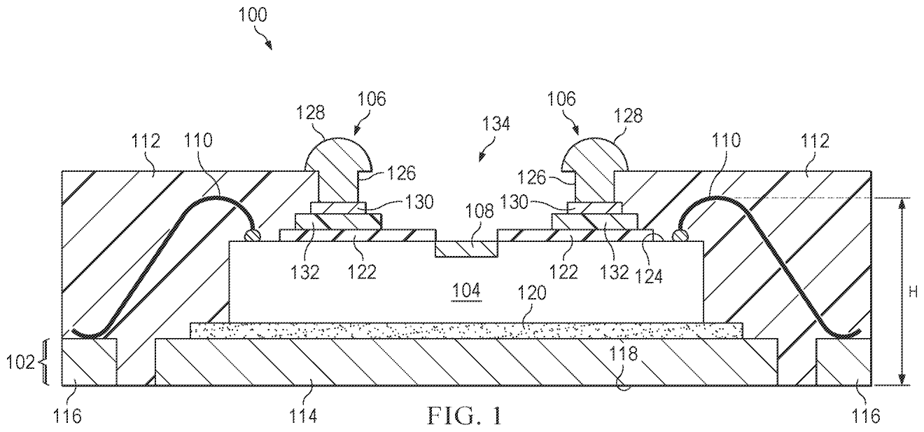

FIG. 1 is a cross-section view of an example electronic device (e.g., open cavity package (OCP)) 100 comprised of a substrate 102, a die 104 disposed on the substrate 102, a ring 106 disposed on the die 104, a sensor 108 disposed on the die 104 and inside the ring 106, wire bonds 110, and a mold compound 112. The electronic device 100 can be comprised of an integrated circuit (IC) and more specifically to an open cavity package (OCP) including, but not limited to a Quad Flat No-Lead (QFN) package, a Quad-Flat Package (QFP), a Ball-Grid Array (BGA) package, etc. Although the example electronic device 100 illustrated in FIG. 1 shows one ring 106 disposed on the die 104 having a sensor 108 disposed inside the ring 106, in other examples the electronic device 100 can include multiple sensors where multiple rings are disposed on the die and a sensor is disposed in each ring. Thus, the electronic device illustrated in FIG. 1 is for illustrative purposes only and is not intended to limit the scope of the invention.

The substrate 102 is comprised of a leadframe that includes a die pad 114 and conductive terminals 116 (e.g., leads, contacts). In alternative examples, the substrate may be comprised of a laminate substrate or a printed circuit board based substrate. For illustrative purposes only, a leadframe based substrate will be described herein and illustrated in the drawings. The die pad 114 may be comprised of a thermal pad that is exposed on an attachment side 118 of the electronic device 100. The thermal pad creates an efficient heat path away from the electronic device 100 to a board (e.g., printed circuit board). In addition, the exposed thermal or die pad 114 also enables a ground connection to the board.

The die 104 attaches to the die pad 114 via a die attach material 120. In one example, the die 104 may optionally include a die polymer layer (e.g., polyimide) 122 disposed on an active (wire bonding) surface 124 of the die 104. The die polymer layer 122 mitigates stress (stress relief layer) between the die 104 and the ring 106. The die polymer layer 122 may also enhance the sensing function and properties of the die and the sensor 108 in some applications such as humidity sensing.

The ring 106 is formed on the die 104 via a plating process as explained below and is comprised of a cylindrical wall 126 and a cap 128. The ring 106 may be formed from a metal such as but not limited to copper, aluminum, nickel, iron, etc. The cap 128 has a shape of a partial circle or a semi-circle and extends beyond each side of the wall 126. Thus, a cross-section view of the ring 106 has a mushroom shape as illustrated in FIG. 1. In one example, the ring 106 may be formed directly on the die 104 or in another example, the ring 106 may be formed on the optional die polymer layer 122. Dimensions of the ring 106 are specific to the sensing application. For example, the ring 106 may have a height (e.g., 70 um-160 um) such that a top of the cap 128 extends above a maximum height H of the wire bonds 110 and may be limited only by the wire bonding capability to produce a low profile wire bond. The ring 106 may have an inner diameter (e.g., 100 um-500 um) that is equal to or greater than a sensor region of the die 104 to prevent affecting the sensor performance.

In addition, one or more layers may optionally be disposed between the ring 106 and the die 104 to mitigate stress (stress relief layer) between the ring 106 and the die 104 and/or for enhancing the sensing properties of the electronic device 100. For example, a plated metal structure 130 having a thickness ranging from 3 um to 10 um may be deposited directly on the die 104 or in another example, deposited on the die polymer layer 122 prior to deposition of the ring 106. In addition, a polymer or metal layer 132 may be deposited directly on the die 104 or in another example, on the die polymer layer 122 prior to deposition of either the ring 106 or the plated metal structure 130 if a seed layer is desired. Thus, different combinations of polymers and metal stacks can be used for stress mitigation and/or to enhance the sensing properties of the electronic device 100. The polymer layer 132 may be comprised of a non-photo-definable or photo-definable chemistry with either positive or negative photo activation. A combination of photo-active, non-photo-active, resist polymers, and electroplated copper structures can be utilized to achieve the desired dimensions and functionality as needed by the application for stress mitigation and/or performance enhancements in sensing.

The sensor 108 is in communication with the active surface 124 of the die 104 and is disposed inside the ring 106. Thus, the ring 106 encircles the sensor 108. In one example, at a wafer level the sensor 108 is integrated into the active surface 124 of the die 104 such that a top surface of the sensor 108 is substantially flush with the active surface 124 of the die 104. In another example, the sensor 108 can be partially integrated into the active surface 124 of the die 104 such that the sensor 108 partially extends above the active surface 124 of the die 104. In still yet another example, the sensor 108 can be disposed of the active surface 124 of the die 104 such that the sensor 108 is fully above the die 104. The sensor 108 may be configured to sense any of a variety of physical properties, such as humidity, light, sound, pressure, bulk acoustic waves, stress, temperature, current, voltage, power, motion, acceleration, magnetic fields, and other physical properties. The active surface 124 of the die 104 may include other circuitry coupled to the sensor 108 that is configured to receive and process signals from the sensor 108 in an appropriate manner. For example, a probing element (not shown) that interrogates the sensor 108 to produce a signal can be disposed below the sensor 108 in the form of an interdigitated lateral comb pattern, across or partially around the sensor 108, or sandwiched above and below the sensor 108. The interrogating signal can be in the form of frequency, current, resistance, capacitance, etc. The wire bonds 110 provide a connection between the active or wire bond surface 124 of the die 104 and the conductive terminals 116.

The mold compound 112 covers all but one surface of the leadframe 102, where the one surface not covered faces away from the electronic device 100. In addition, the mold compound 112 encapsulates the wire bonds 110 and covers a portion of the die 104. As explained below, the mold compound 112 abuts an outer surface of the ring 106 and is thus prevented from entering an interior of the ring 106 and thus does not cover the sensor 108. As a result, a cavity 134 is formed in the mold compound 112 thereby forming the open cavity electronic device 100.

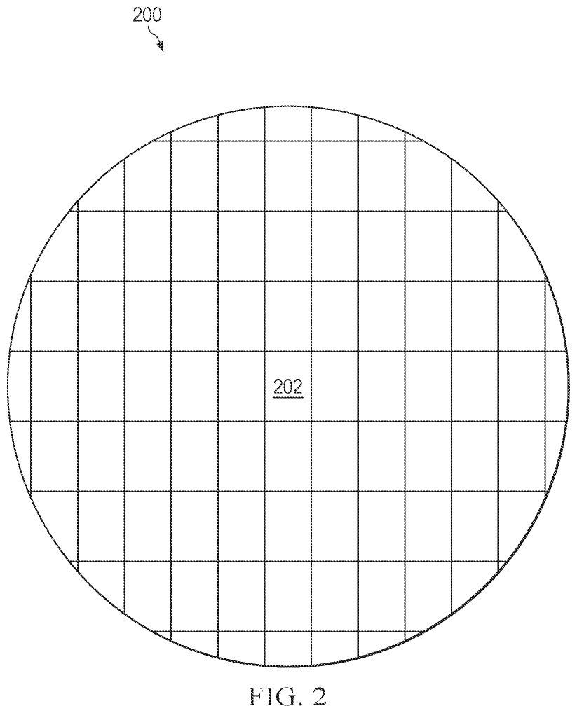

FIGS. 2-19 illustrate a fabrication process associated with the formation of the electronic device (e.g., OCP) 100 illustrated in FIG. 1. Though depicted sequentially as a matter of convenience, at least some of the actions shown can be performed in a different order and/or performed in parallel. Alternatively, some implementations may perform only some of the actions shown. Still further, although the example illustrated in FIGS. 2-19 is an example method illustrating the example configuration of FIG. 1, other methods and configurations are possible. It is understood that although the method illustrated in FIGS. 2-19 depicts the fabrication process of a single open cavity electronic device, the process applies to an array of OCP's. Thus, after fabrication of the array of OCP's the array is singulated to separate the OCP's from the array.

FIGS. 2-11 illustrate a fabrication process associated with the formation of the dies for the electronic device 100 illustrated in FIG. 1. Specifically, Referring to FIG. 2, FIG. 2 is a schematic diagram of a wafer 200, in accordance with various examples. For example, the wafer 200 may be a silicon wafer. The wafer 200 comprises multiple dies 202. The manufacturing techniques described below may be performed on individual dies 202 (post-singulation), or the techniques may be more efficiently performed on a mass scale, e.g., simultaneously on multiple dies 202 of the wafer 200 (pre-singulation). For convenience and clarity, the remaining drawings show one die 202, with the understanding that the processes described herein as being performed on the die 202 may also be performed (e.g., sequentially performed, simultaneously performed) on the remaining dies 202 of the wafer 200.

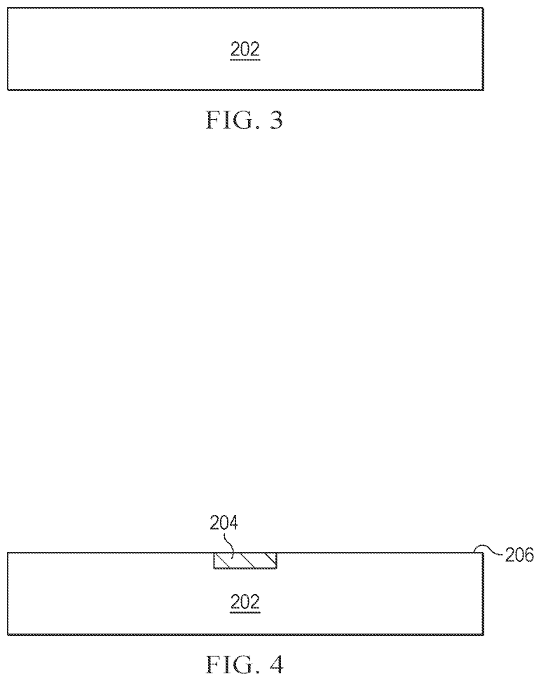

FIG. 3 illustrates a cross section view of a single die 202 singulated from the wafer 200. A sensor 204 is integrated into an active (wire bonding) surface 206 of the die 202 such that a top surface of the sensor 204 is substantially flush with the active surface 206 of the die 202 resulting in the configuration of FIG. 4. As explained, however, the sensor 204 can be partially integrated into the active surface 206 of the die 202 or can be disposed on the active surface 206 of the die 202. For example, in an application where the sensor 204 is configured to sense humidity, the sensor 204 is integrated into the die 202 as a lateral capacitor. The lateral capacitor uses a transducer medium (e.g., polyimide) on top as a functionalized material that will change a di-electric constant with varying levels of humidity resulting in a change of capacitance.

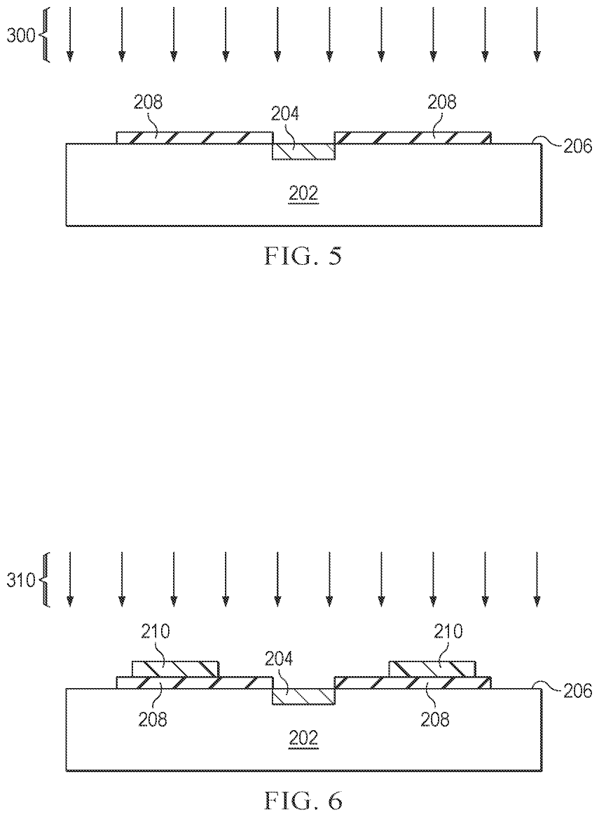

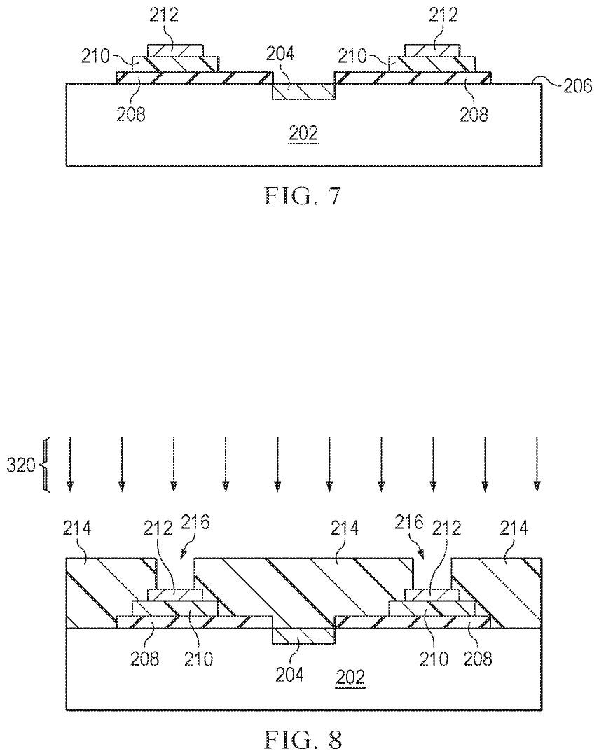

An optional die polymer layer 208 (e.g., polyimide) is deposited on the active surface 206 of the die 202 resulting in the configuration in FIG. 5. The configuration in FIG. 5 undergoes a first deposition process 300 to deposit and pattern an optional stress relief polymer layer 210 on the die 202 or on the optional die polymer layer 208 resulting in the configuration in FIG. 6. The configuration in FIG. 6 undergoes a second deposition process 310 to deposit an optional metal structure (e.g., copper) 212 having a thickness ranging from 3 um to 10 um on the polymer layer 210 resulting in the configuration in FIG. 7. Those familiar in the art of electroplating layers on a wafer will recognize that a conductive seed layer must be deposited to blanket the wafer effectively creating an electrically conductive surface to initiate the electro-chemical deposition of the metal. Once electroplating the structures of interest has been completed this seed layer will be etched away. For simplicity only the major metal structures are shown in each figure with an understanding they were plated using a seed metal such as but not limited to Ti, TiW, TiW+Cu.

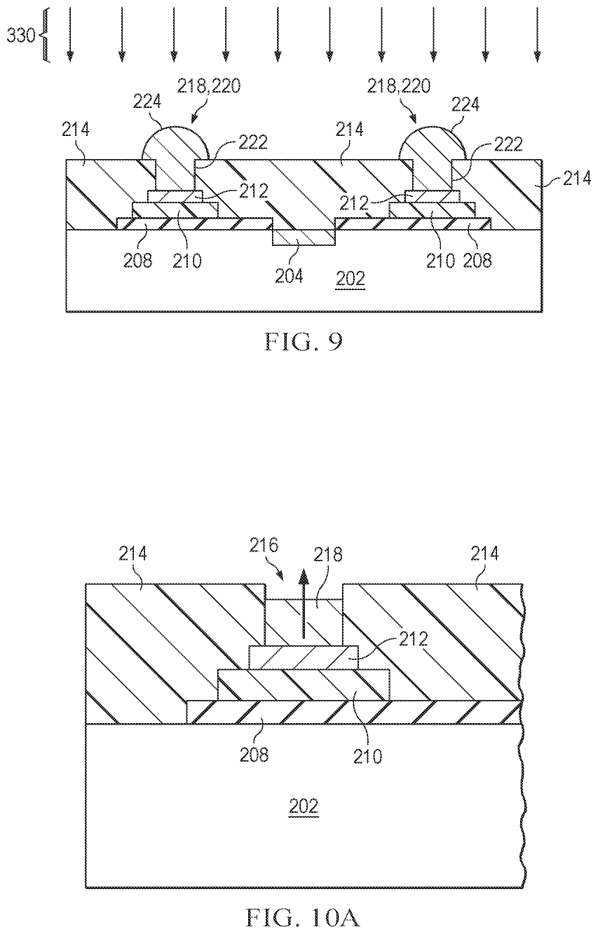

Referring to FIG. 8, a photoresist material layer 214 overlies the die 202 and is patterned and developed to expose a ring shaped opening 216 in the photoresist material layer 214 in accordance with a pattern. The photoresist material layer 214 can have a thickness that varies in correspondence with the wavelength of radiation used to pattern the photoresist material layer 214. The photoresist material layer 214 may be formed over the die 202 via spin-coating or spin casting deposition techniques, selectively irradiated (e.g., via deep ultraviolet (DUV) irradiation) and developed to form the ring shaped opening 216.

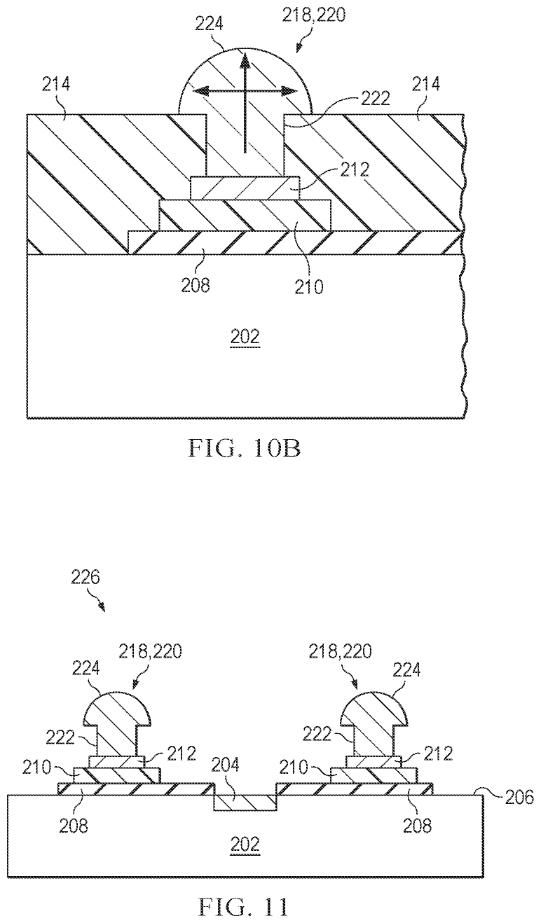

The configuration in FIG. 8 undergoes an electro-plating process 320 to deposit metal plating (e.g., copper) 218 in the ring shaped opening 216 resulting in the configuration in FIG. 9. FIGS. 10A and 10B illustrate close-up cross section views of the plating process as the metal plating fills 218 the ring shaped opening 216 in the photoresist material layer 214. Referring to FIG. 10A, while the metal plating 218 is being plated within walls of the photoresist material layer 214, the metal plating 218 plates in a vertical direction as indicated by the arrow. Once the metal plating 218 reaches a top surface of the photoresist material layer 214, the metal plating 218 continues to plate in the vertical direction indicated by the arrow. The metal plating 218, however, also plates in a horizontal direction indicated by the double arrow, sec FIG. 10B. Thus, once the metal plating 218 reaches the top of the photoresist material layer 214, the metal plating 218 plates both vertically and horizontally on a surface of the photoresist material layer 214.

The metal plating 218 forms a ring 220 on the die 202 that is comprised of a cylindrical wall 222 and a cap 224. The cap 224 has a shape of a partial circle or a semi-circle and extends beyond each side of the cylindrical wall 222. Thus, a cross-section view of the ring 220 has a mushroom shape as illustrated in FIGS. 9 and 10B. In addition, a secondary plating option can be utilized before stripping off the photoresist to help passivate the metal structure. Plating finishes such as OSP, Matte Sn, SnAg, electroless Sn, electroless Ag, Ni, NiPd, NiAu, NiPdAu, and electroless NiAu (ENiG) etc. are well known techniques familiar with electronic assembly.

Once the plating process 320 is complete, the photoresist material layer 214 is removed via a solvent stripping process 330. In addition, a portion of the metal structure 212, which blankets the entire wafer (not shown for simplicity) is etched during an etching process such that the metal structure 212 extending beyond the cylindrical wall 222 of the ring 220 is left intact resulting in the configuration in FIG. 11. The metal structure 212 distributes the weight of the ring 220 thereby spreading the stress from the ring 220 to prevent cracking in the polymer layer 10. The configuration in FIG. 11 represents a single die assembly 226 that includes the die 202 and the sensor 204 disposed inside the ring 220.

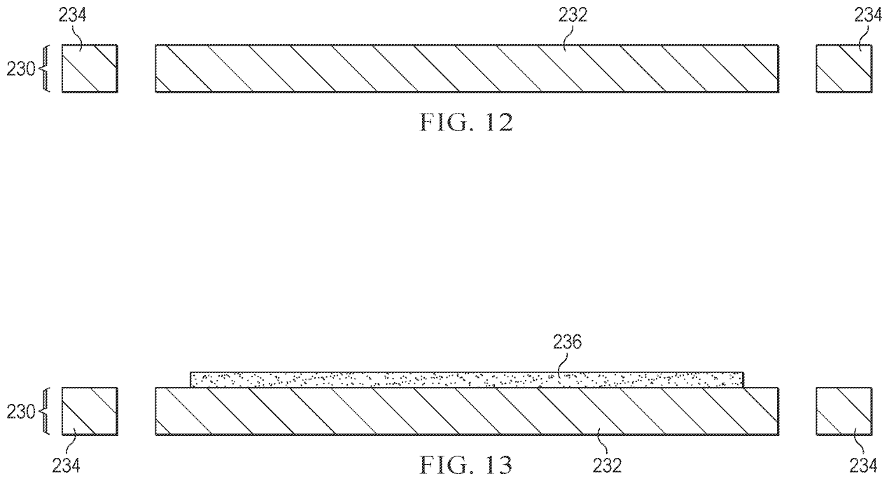

FIGS. 12-19 illustrate a fabrication process associated with the process of placing the die assembly 226 on a substrate and a molding process to thereby fabricate the electronic device 100 illustrated in FIG. 1. In the following description, the substrate is comprised of a leadframe. It is to be understood that in alternative examples, the substrate may be comprised of a laminate substrate or a printed circuit board based substrate. For illustrative purposes only, a leadframe based substrate will be described herein and illustrated in the drawings.

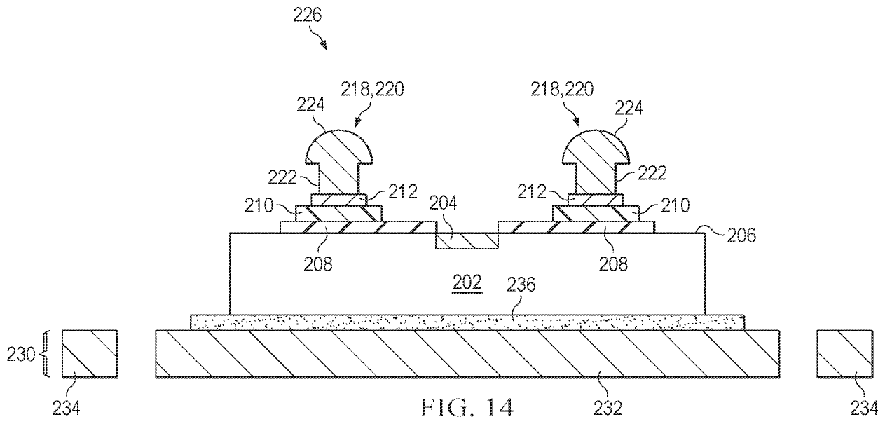

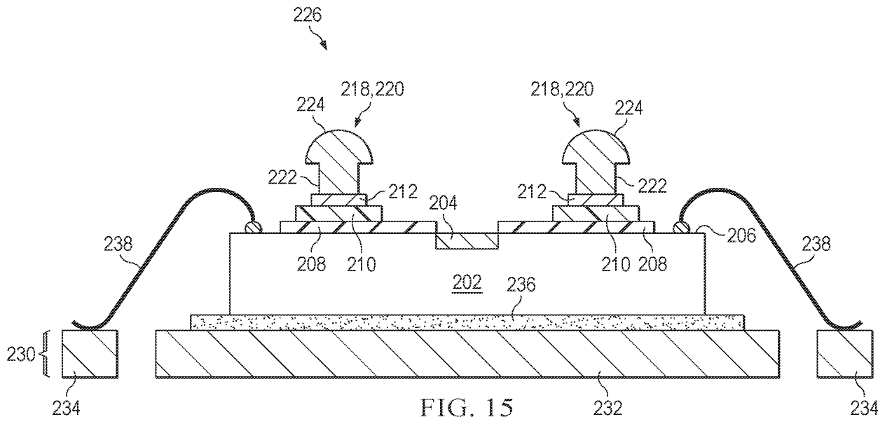

FIG. 12 illustrates a cross section view of a leadframe 230 that includes a die pad 232 and conductive terminals 234 (e.g., leads, contacts). A die attach material 236 is deposited on a surface of the die pad 232 resulting in the configuration in FIG. 13. For simplicity the dispensed die attach technique is referenced, however, other die attach techniques such as using a die attach film pre applied to the back of the wafer can also be utilized. The die assembly 226 is then picked and placed on the die attach material 236 resulting in the configuration in FIG. 14. Wire bonds 238 are attached from the active or wire bond surface 208 of the die 202 to a surface of each of the conductive terminals 234 resulting in the configuration in FIG. 15.

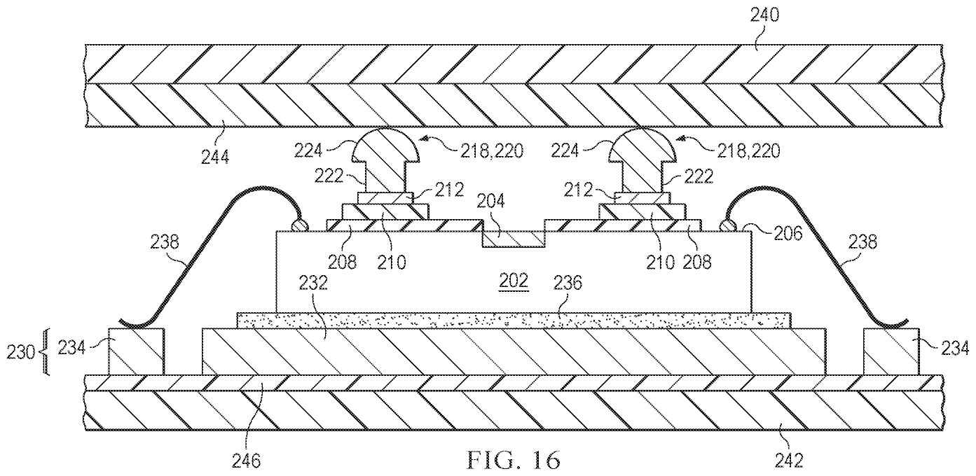

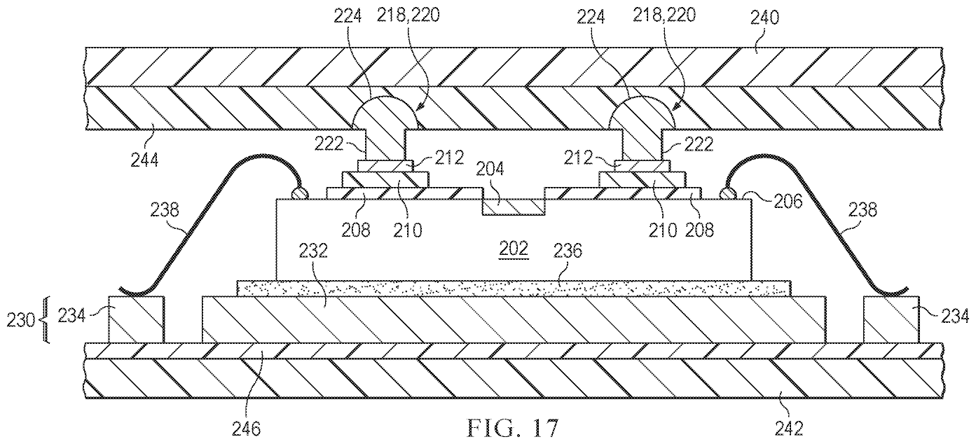

Referring to FIG. 16, the configuration in FIG. 15 is placed into a mold chase that includes a first (top) member 240 and a second (bottom) member 242. First and second film assist molding (e.g., a non-stick polymer, Teflon, etc.) 244, 246 are disposed in the mold chase. Specifically, the first film assist molding 244 operates in conjunction with the first member 240 and the second film assist molding operates in conjunction with the second member 242. The first and second members 240, 242 of the mold chase then clamp the electronic device 100 as illustrated in FIG. 16. A vacuum is taken between the top member 240 of the mold chase and the first film assist molding 244 to hold the film in place. The bottom member 242 of the mold chase and the second film assist molding 246 also utilizes the same vacuum technique to hold the film in place. Once the mold tool fully clamps, the first film assist molding 244 contacts the cap 224 of the ring 220 to provide a seal around the cap 224 as illustrated in FIG. 17. Thus, the first film assist molding 244 seals off the interior of the ring 220.

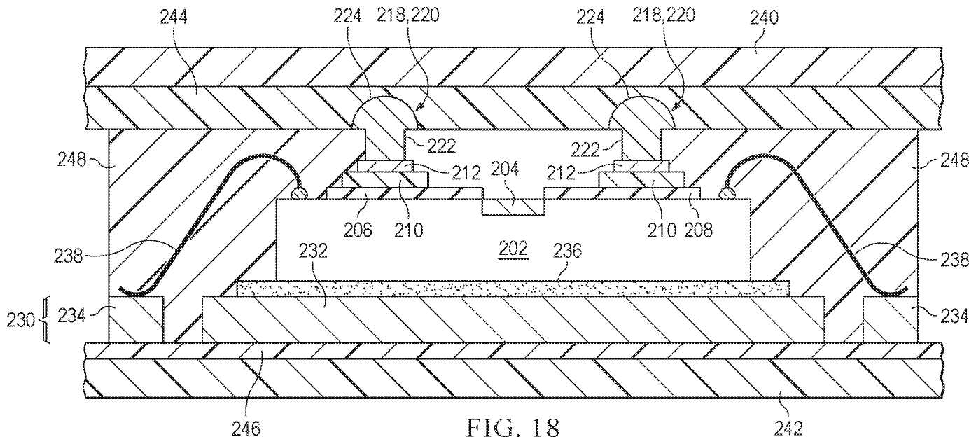

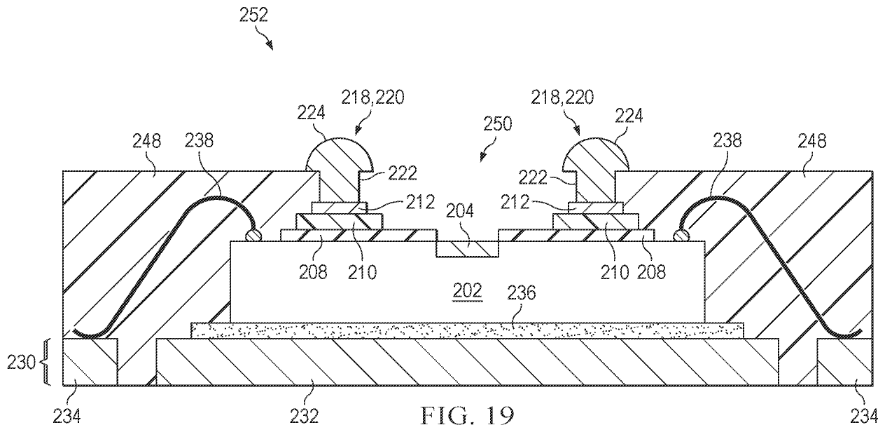

A mold compound 248 is injected into the mold chase as illustrated in FIG. 18. The mold compound 248 covers all but one surface of the leadframe 230, where the one surface not covered faces away from the electronic device 100. In addition, the mold compound 248 encapsulates the wire bonds 238 and covers a portion (both sides) of the die 202. The mold compound 248, however, abuts an outer surface of the ring 220 and is prevented from entering the interior of the ring 220 due to the first film assist molding 244 contacting and thus providing the seal around the cap 224 of the ring 220. More specifically, partially circular shape of the cap 224 has a larger surface area as opposed to a ring without the cap. Thus, there is more contact between the cap 224 and the film assist molding 244 to prevent the mold compound 248 from entering the interior of the ring 220. As a result, a cavity 250 is formed in the mold compound 248 where the sensor 204 resides thereby exposing the sensor 204 to the environment to which it is designed to sense. Finally, the electronic device is removed from the mold chase resulting in the open cavity electronic device 252 illustrated in FIG. 19.

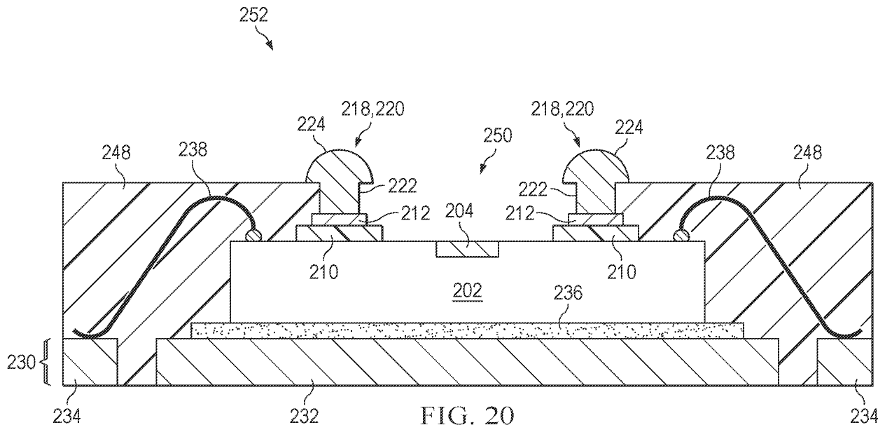

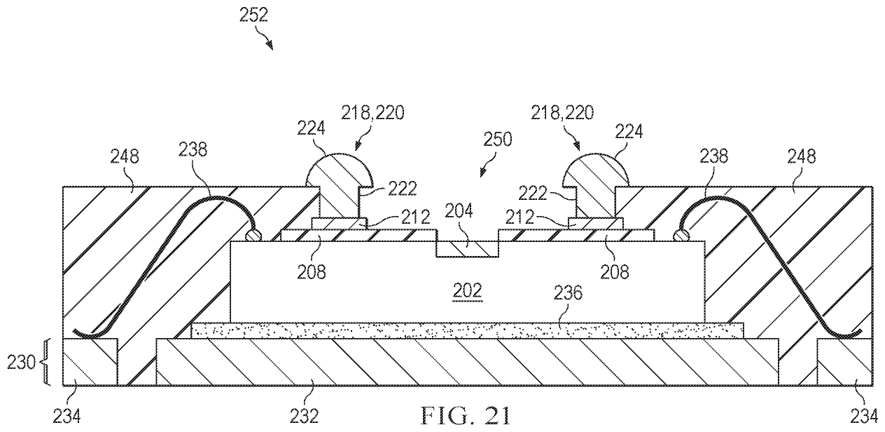

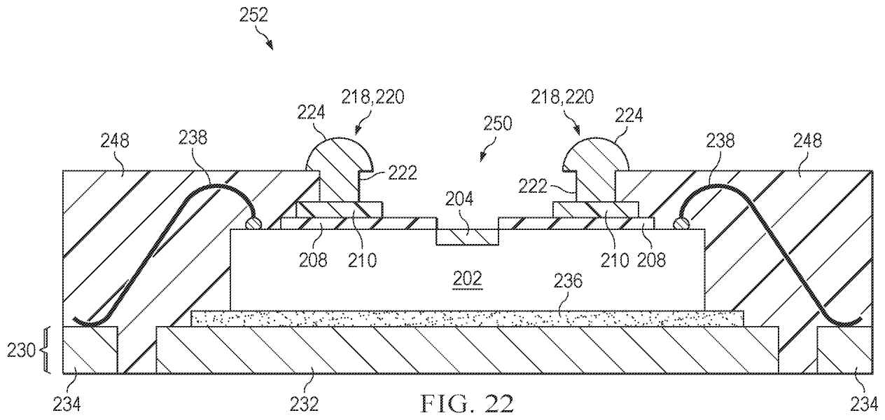

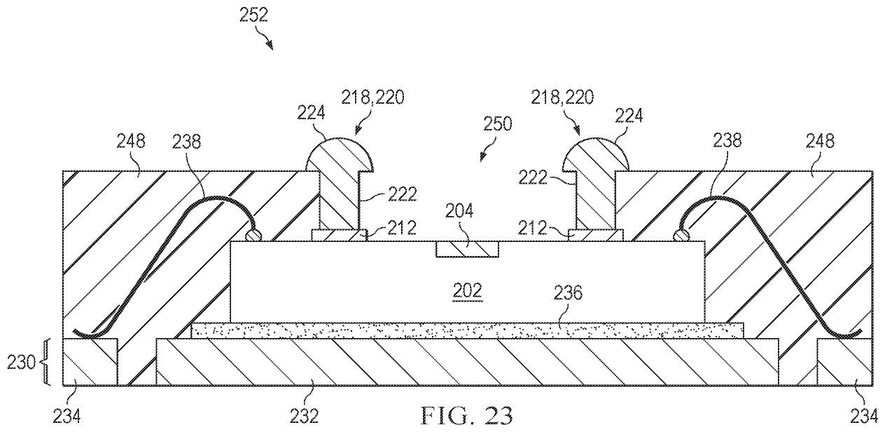

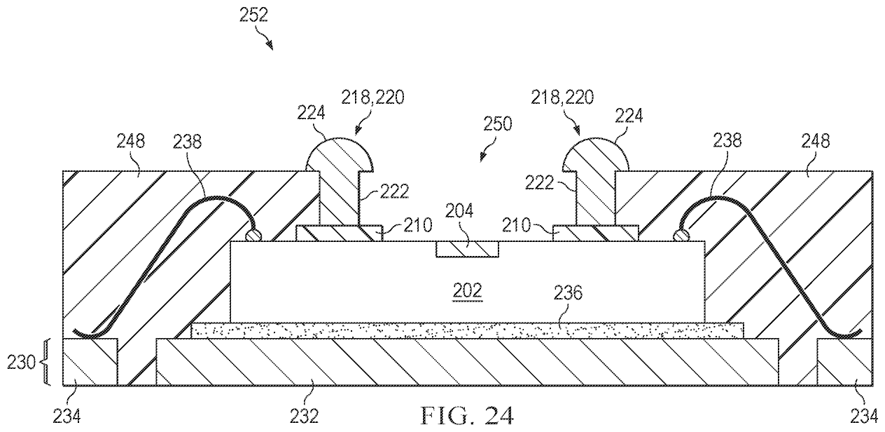

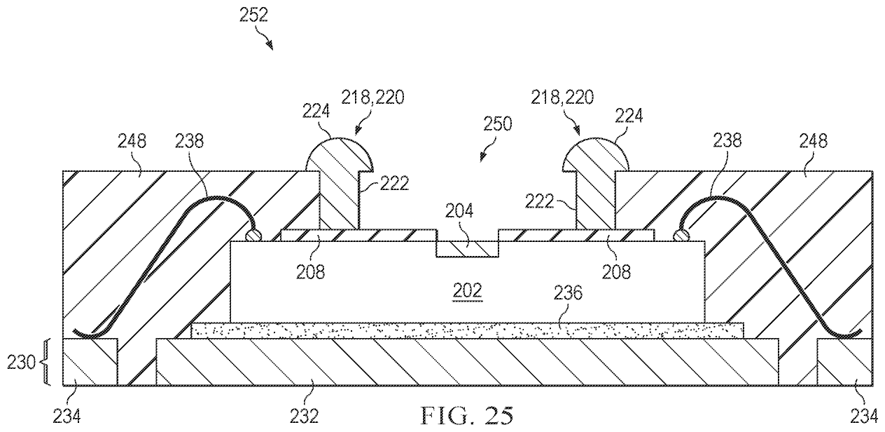

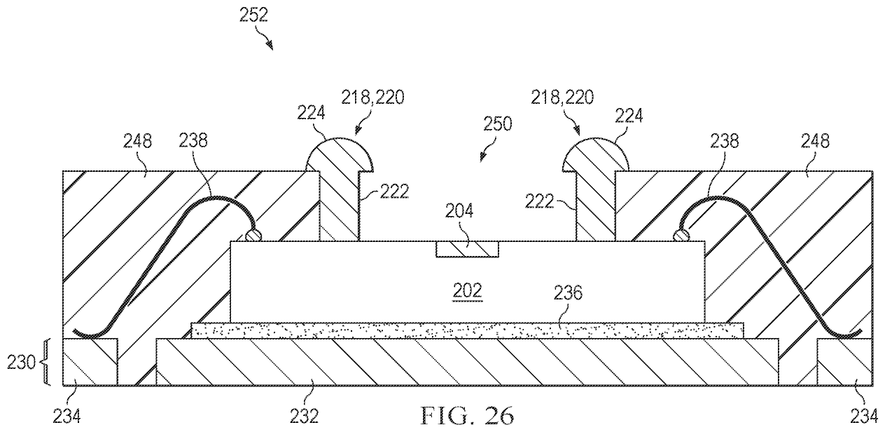

FIGS. 20-26 illustrate modifications of the electronic device illustrated in FIGS. 1 and 19. As described above, the die polymer layer 122, 208, the polymer or metal layer 132, 210, and the plated metal structure 130, 212 are optional layers. Thus, FIG. 20 illustrates a cross section view of a modification of the electronic device of FIGS. 1 and 19 that does not include the optional die polymer layer 122, 208. FIG. 21 illustrates a cross section view of a modification of the electronic device of FIGS. 1 and 19 that does not include an optional polymer or metal layer 132, 210. FIG. 22 illustrates a cross section view of a modification of the electronic device of FIGS. 1 and 19 that does not include an optional plated metal structure 130, 212. FIG. 23 illustrates a cross section view of a modification of the electronic device of FIGS. 1 and 19 that does not include the optional die polymer layer 122, 208 and the optional polymer or metal layer 132, 210. FIG. 24 illustrates a cross section view of a modification of the electronic device of FIGS. 1 and 19 that does not include the optional die polymer layer 122, 208 and the optional plated metal structure 130, 212. FIG. 25 illustrates a cross section view of a modification of the electronic device of FIGS. 1 and 19 that does not include the optional polymer or metal layer 132, 210 and the optional plated metal structure 130, 212. FIG. 26 illustrates a cross section view of a modification of the electronic device of FIGS. 1 and 19 that does not include the optional die polymer layer 122, 208, the optional polymer or metal layer 130, 212, and the optional plated metal structure 130, 212.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a substrate;
a die having an active surface, the die being disposed on the substrate;
a sensor in communication with the active surface of the die;
a ring encircling the sensor, the ring including a cylindrical wall and a cap, the cap having a partial circular shape that extends beyond each side of the wall;
a mold compound covering the die and abutting an outer surface of the wall thereby forming a cavity in the mold compound to expose the sensor to an environment external to the electronic device.

2. The electronic device of claim 1 further comprising a metal structure disposed between the ring and the die.

3. The electronic device of claim 2 further comprising a stress relief layer disposed between the metal structure and the die.

4. The electronic device of claim 1 further comprising at least one stress relief layer and/or at least one metal structure disposed between the ring and the die.

5. The electronic device of claim 1, wherein an inner diameter of the ring is equal to or greater than a sensor region of the die to prevent affecting sensor performance.

6. The electronic device of claim 1 further comprising wire bonds attached to the active surface of the die and to the substrate.

7. The electronic device of claim 6, wherein the ring has a height that extends above a maximum height of the wire bonds.

8. The electronic device of claim 6, wherein the substrate is a leadframe that includes a die pad and conductive terminals, the die being attached to the die pad via a die attach material and the wire bonds being attached to the conductive terminals.

9. A method comprising:
providing a die including a sensor;
depositing a ring on the die, the die encircling the sensor;
placing the die on a substrate;
placing the die and the substrate in a mold chase, the mold chase including film assist material;
clamping the die with the mold chase, the film assist material contacting a cap of the ring;
injecting a mold compound into the mold chase, the mold compound abutting an outer surface of the ring, the ring and the film assist material preventing the mold compound from entering an interior of the ring.

10. The method of claim 9, wherein prior to placing the die and the substrate in a mold chase, the method further comprising attaching wire bonds from the die to the substrate.

11. The method of claim 9, wherein prior to depositing a ring on the die, the method further comprising depositing a die polymer layer on the die.

12. The method of claim 11 further comprising depositing a stress relief layer on the die polymer layer.

13. The method of claim 12 further comprising depositing a metal structure on the stress relief layer.

14. The method of claim 9, wherein depositing a ring on the die includes electroplating metal in a vertical direction within a ring shaped opening in a photoresist material layer and electroplating the metal in the vertical direction and a horizontal direction on a surface of the photoresist material layer as the metal exceeds a height of the photoresist material layer.

15. The method of claim 14, wherein the metal electroplated in the ring shaped opening forms a cylindrical wall of the ring and the metal electroplated on the surface of the photoresist material layer forms a cap of the metal ring, the cap having a partial circular shape and extending beyond each side of the wall.

16. A method comprising:
fabricating a die assembly comprising:
providing a die having an active surface, the die including a sensor;
depositing a stress relief layer on the active surface of the die;
depositing a metal structure on the stress relief layer;
depositing a photoresist material layer over the die, the photoresist material patterned to form a ring shaped opening on the metal structure; and
electroplating metal on the metal structure in the ring shaped opening to form a metal ring;
placing the die assembly on a substrate;
placing the die assembly and the substrate in a mold chase, the mold chase including film assist material;
clamping the die assembly and the substrate with the mold chase, the film assist material contacting a cap of the metal ring; and
injecting a mold compound into the mold chase, the mold compound abutting an outer surface of the metal ring, the metal ring and the film assist material preventing the mold compound from entering an interior of the metal ring.

17. The method of claim 16, wherein electroplating metal on the metal structure in the ring shaped opening includes electroplating the metal in a vertical direction within the ring shaped opening and electroplating the metal in the vertical direction and a horizontal direction on a surface of the photoresist material layer as the metal exceeds a height of the photoresist material layer.

18. The method of claim 17, wherein the metal electroplated in the ring shaped opening forms a cylindrical wall of the metal ring and the metal electroplated on the surface of the photoresist material layer forms a cap of the metal ring, the cap having a partial circular shape and extending beyond each side of the wall.

19. The method of claim 16, wherein the substrate is a leadframe, the leadframe including a die pad and conductive terminals, wherein the die assembly is attached to the die pad via a die attach material, and wherein prior to placing the die assembly and the substrate in a mold chase, the method further comprising attaching wire bonds from the active surface of the die to the conductive terminals.

20. The method of claim 16, wherein prior to depositing a stress relief layer on the active surface of the die, the method further comprising depositing a die polymer layer on the active surface of the die.
